(19) United States
(12) Patent Application Publication
(10) Pub. No.: US 2019/0264322 A1
(43) Pub. Date: Aug. 29, 2019

(54) CONDUCTIVE DIAMOND PARTICLES, CONDUCTIVE DIAMOND ELECTRODE, AND TESTING DEVICE

(71) Applicants: Takeshi KONDO, Tokyo (JP); Keito NAKAJIMA, Tokyo (JP); Tatsuo AIKAWA, Tokyo (JP); Makoto YUASA, Tokyo (JP); Takahiro OSASA, Kanagawa (JP); Akihiro KOTSUGAI, Shizuoka (JP)

(72) Inventors: Takeshi KONDO, Tokyo (JP); Keito NAKAJIMA, Tokyo (JP); Tatsuo AIKAWA, Tokyo (JP); Makoto YUASA, Tokyo (JP); Takahiro OSASA, Kanagawa (JP); Akihiro KOTSUGAI, Shizuoka (JP)

(21) Appl. No.: 16/348,308

(22) PCT Filed: Oct. 26, 2017
(86) PCT No.: PCT/JP2017/038760

§ 371 Date: May 8, 2019

(30) Foreign Application Priority Data
Nov. 11, 2016 (JP) 2016-221016

(51) Int. Cl. C23C 16/27; C01B 32/26; G01N 27/30

(52) U.S. Cl. CPC C23C 16/278; C01B 32/26; C01P 2002/82; C01P 2004/03; G01N 27/308

(57) ABSTRACT

Provided are conductive diamond particles including: particulate bases; and boron-doped diamond films on at least part of surfaces of the particulate bases, wherein an average particle diameter of the conductive diamond particles is greater than 0.5 micrometers, and wherein in Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

### TECHNICAL FIELD

The present disclosure relates to conductive diamond particles and a conductive diamond electrode containing the same, and a testing device using the same.

### BACKGROUND ART

Typically, boron-doped diamond is formed in a thin film shape on a flat plate-shaped base such as a silicon wafer by a chemical vapor deposition (CVD) method. This film formation method needs the reaction space to be under high-vacuum conditions. This makes equipment upsizing difficult. Hence, it hitherto has been difficult to obtain a boron-doped diamond electrode having a large area. There is also a problem that an obtained boron-doped diamond thin film is extremely hard, and it is difficult to apply to the boron-doped diamond thin film, processing needed for the boron-doped diamond thin film to be used as an electrochemical electrode.

To solve these problems, in recent years, attempts have been made to make boron-doped diamond into a particulate form before processing the boron-doped diamond into an electrode (see, for example, PTLs 1 to 3). For example, mixing with a binding agent, coating, or attaching on or embedding in a conductive base can be applied to particulate boron-doped diamond. By these methods, an electrode having an arbitrary size and an arbitrary form can be easily produced.

Examples of how to produce the boron-doped diamond particles include a method of stripping a boron-doped diamond thin film formed on a flat plate-shaped base and subsequently pulverizing and classifying the boron-doped diamond thin film, and a method of forming boron-doped diamond films on the circumferences of particulate bases (see, for example PTL 4 and NPLs 1 and 2).

### CITATION LIST

### Patent Literature

[PTL 1] Japanese Unexamined Patent Application Publication No. 2005-089789
[PTL 2] Japanese Translation of PCT International Application Publication No. JP-T-2007-528495
[PTL 3] Japanese Patent No. 4685089
[PTL 4] Japanese Unexamined Patent Application Publication No. 2013-076130

### Non Patent Literature

[NPL 1] T. Kondo and other 6 persons, “Screen-printed Modified Diamond Electrode for Glucose Detection”, Chem. Lett., 2013, Volume 42, pp. 352-354
[NPL 2] D. Y. Kim and other 2 persons, “Preparation and Characterization of Glassy Carbon Powder Modified with a Thin Layer of Boron-Doped Ultrananocrystalline Diamond (B-UNCD)”, Chem. Mater., 2009, Volume 21, pp. 2,705-2,713

### SUMMARY OF INVENTION

### Technical Problem

The present disclosure has an object to provide conductive diamond particles having a high crystal quality and capable of producing a conductive diamond electrode and a testing device that are excellent in chemical stability and detection sensitivity.

### Solution to Problem

According to one aspect of the present disclosure, conductive diamond particles contain particulate bases and boron-doped diamond films on at least part of surfaces of the particulate bases. An average particle diameter of the conductive diamond particles is greater than 0.5 micrometers. In Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

### Advantageous Effects of Invention

The present disclosure can provide conductive diamond particles having a high crystal quality and capable of producing a conductive diamond electrode and a testing device that are excellent in chemical stability and detection sensitivity.

### BRIEF DESCRIPTION OF DRAWINGS

FIG. 1 is a schematic cross-sectional view illustrating an example of conductive diamond particles of the present disclosure.

FIG. 2A is a perspective view illustrating an example of a conductive diamond electrode of the present disclosure.

FIG. 2B is an exploded perspective view illustrating an example of a conductive diamond electrode of the present disclosure.

FIG. 3A is an exemplary view illustrating an example of a BDD ink used in the present disclosure in a state before dried.

FIG. 3B is an exemplary diagram illustrating an example of a BDD ink used in the present disclosure in a state after dried.

FIG. 4 is a schematic diagram illustrating an example of an MPCVD apparatus used for producing boron-doped diamond particles (BDDP).

FIG. 5A is a scanning electron microscopic image of DP.

FIG. 5B is a scanning electron microscopic image of BDDP.

FIG. 6A is a Raman spectrum of BDDP produced in Example 1.

FIG. 6B is a Raman spectrum of BDDP produced in Comparative Example 1.

FIG. 7 is a flow diagram illustrating a method for preparing a BDD ink.

FIG. 8 is a flow diagram illustrating a process for producing a conductive diamond electrode.

FIG. 9 is a CV graph of a conductive diamond electrode of Example 6 in a hexaammineruthenium (III) chloride (1.0 mmol/L)-perchloric acid aqueous solution (0.1 mol/L).

### DESCRIPTION OF EMBODIMENTS

(Conductive Diamond Particles)

Conductive diamond particles of the present disclosure contain particulate bases and boron-doped diamond films on at least part of surfaces of the particulate bases.

An average particle diameter of the conductive diamond particles is greater than 0.5 micrometers. In Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

The conductive diamond particles of the present disclosure are based on the following finding. The method of stripping a boron-doped diamond thin film formed on a flat plate-shaped base and subsequently pulverizing and classifying the boron-doped diamond thin film can ensure the boron-doped diamond particles to be obtained completely the same quality as the boron-doped diamond thin film, but needs a lot of effort and time for the stripping step, the pulverizing step, and the classifying step, and still has the problem of difficulty obtaining a thin film having a large area, leading to an even worse productivity.

The conductive diamond particles of the present disclosure are also based on the following finding. Existing methods for forming boron-doped diamond films on surfaces of particulate bases have been found, as a result of studies of the present inventors, to have sp² carbon mixed into the boron-doped diamond films, to degrade the crystal quality in some cases. Diamond is formed only of spa carbon, whereas boron-doped diamond films to be formed on surfaces of particulate bases are simultaneously accompanied by occurrence and mixing of a graphite component containing sp² carbon. Synthetic diamond in which sp² carbon is mixed in a large amount has a low crystal quality and is undesirable.

As a result of earnest studies for solving the problems described above, the present inventors have found the following. When obtaining conductive diamond particles containing particulate bases and boron-doped diamond films on at least part of surfaces of the particulate bases, preferably using bases having an average particle diameter of greater than 0.4 micrometers as the particulate bases and forming boron-doped diamond films in a manner that an average particle diameter of conductive diamond particles to be obtained will be greater than 0.5 micrometers can significantly reduce sp² carbon to be mixed in the boron-doped diamond films and provide conductive diamond particles having a high crystal quality.

Accordingly, the conductive diamond particles of the present disclosure are characterized by containing particulate bases and boron-doped diamond films on at least part of surfaces of the particulate bases, and characterized in that an average particle diameter of the conductive diamond particles is greater than 0.5 micrometers and that in Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

<Conductive Diamond Particles>

The conductive diamond particles contain particulate bases and boron-doped diamond films on at least part of surfaces of the particulate bases. The surfaces of the particulate bases may be partially coated with the boron-doped diamond films, or the surfaces of the particulate bases may be wholly coated with the boron-doped diamond films.

Conductivity of the conductive diamond particles means a powder conductivity of 0.01 S/cm or higher.

The material used as the particulate bases is not particularly limited and may be appropriately selected depending on the intended purpose so long as the material is not melted and deformed by heat applied during formation of boron-doped diamond films. Examples of the material of the particulate bases include natural or synthetic diamond particles such as insulating diamond particles commercially available as abrasive grains, metal particles of, for example, silicon and molybdenum, metal alloy particles of, for example, boron nitride, and metal oxide particles of, for example, quartz and alumina. One of these materials may be used alone or two or more of these materials may be used in combination. Among these materials, at least any one selected from the group consisting of natural diamond particles and synthetic diamond particles is preferable.

The average particle diameter of the particulate bases is preferably greater than 0.4 micrometers and more preferably 1 micrometer or greater. As a result of earnest studies, the present inventors have found that the same boron-doped diamond film formation procedure result in a higher film formation speed as the particle diameter of the particulate bases is greater, to enable suppression of sp² carbon mixing into boron-doped diamond films. An average particle diameter of the particulate bases of 0.4 micrometers or less is undesirable because a film formation speed needed for suppression of sp² carbon mixing cannot be obtained.

The average particle diameter of the particulate bases can be measured with, for example, a dynamic light scattering measuring instrument (DLS measurement, NICOMP 380 available from Particle Sizing Systems, LLC).

The shape of the particulate bases is not particularly limited, may be appropriately selected depending on the intended purpose, and may be a true sphere, a cube, and a polyhedron that have an aspect ratio of around 1, or may be shapes having an aspect ratio of greater than 1.

The method for forming the boron-doped diamond films is not particularly limited and may be appropriately selected depending on the intended purpose. Examples of the method include chemical vapor deposition methods (CVD methods) such as a thermal CVD method, a plasma CVD method, and a hot-filament CVD method, physical vapor deposition methods (PVD methods) such as an ion beam method and an ionic vapor deposition method, and a high temperature and high pressure method. Among these methods, the plasma CVD method is preferable.

In the chemical vapor deposition methods, the carbon source and the boron source, which are the materials of the boron-doped diamond films, are not particularly limited and may be appropriately selected depending on the intended purpose. As the carbon source, for example, methane and acetone can be used. As the boron source, for example, diborane, trimethyl boron, and trimethoxy borane can be used.

In the boron-doped diamond films, the amount of boron doped in diamond is preferably 10 ppm or greater, more preferably 1,000 ppm or greater, and yet more preferably 10,000 ppm or greater of carbon that constitutes diamond (in other words, the ratio of boron concentration in the crystal is preferably from 10²⁰ cm⁻³ through 10²² cm⁻³). In this range, conductive diamond particles having a sufficient conductivity can be obtained.

The amount of boron doped in diamond can be measured by, for example, a secondary ion mass spectrometry method.

The average particle diameter of the conductive diamond particles is preferably greater than 0.5 micrometers, more preferably 0.6 micrometers or greater but less than 8.0 micrometers, and yet more preferably 1.0 micrometer or greater but less than 5.0 micrometers.

When conductive diamond particles having an average particle diameter of greater than 0.5 micrometers are used, it is easier for conductive diamond particle groups to be formed in a conductive diamond electrode. This provides an advantage that an electrode having a good conductivity is obtained.

The average particle diameter can be measured with, for example, a dynamic light scattering measuring instrument (DLS measurement, NICOMP 380 available from Particle Sizing Systems, LLC).

In Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

It is known that a peak at 1,580 cm⁻¹ in the Raman spectrum corresponds to a sp² carbon component and a peak at 1,332 cm⁻¹ corresponds to a diamond crystal (see, for example, Y. C. Wang and other 3 persons, “Resonant Raman scattering studies of Fano-type interference in boron doped diamond”, J. Appl. Phys., 2002, Volume 92, p. 7,253).

Hence, the intensity ratio (1,580 cm⁻¹/1,332 cm⁻¹) is correlated with the relative amount of the sp² carbon component in the boron-doped diamond films. It is preferable that the ratio of the intensity of the conductive diamond particles at 1,580 cm⁻¹ to the intensity of the conductive diamond particles at 1,332 cm⁻¹ be less than 0.090, because the amount of sp² carbon mixed in the boron-doped diamond films is adequate.

The Raman spectrum can be measured with, for example, a Raman spectrometer (NSR-5100, available from JASCO Corporation).

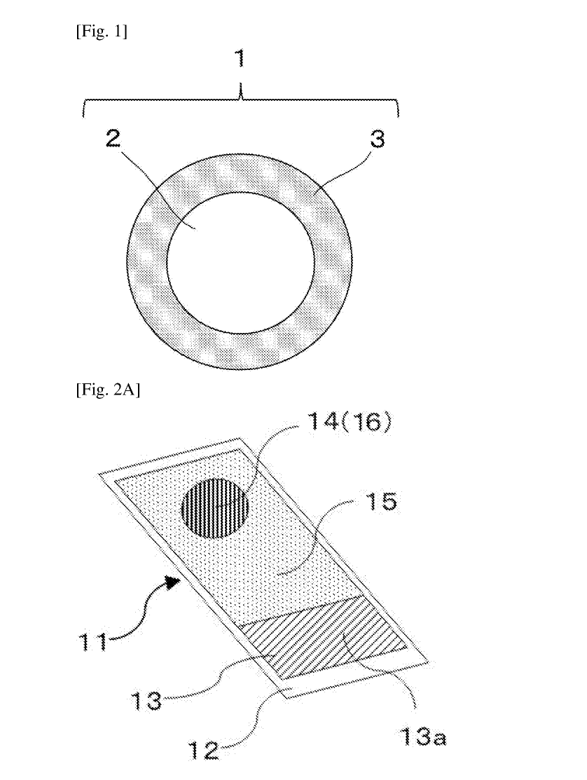

FIG. 1 is an exemplary diagram of a cross-sectional structure of a conductive diamond particle of the present disclosure. As illustrated in FIG. 1, in a conductive diamond particle 1, a boron-doped diamond film 3 is formed on a surface of a particulate base 2.

The conductive diamond particles of the present disclosure have a high crystal quality and can be favorably used in various fields, and can be favorably used in a conductive diamond electrode described below.

(Conductive Diamond Electrode)

A conductive diamond electrode of the present disclosure includes a current collector and conductive diamond particles provided on the current collector and electrically coupled to the current collector, and further includes other members as needed.

As the conductive diamond particles, the conductive diamond particles of the present disclosure are used.

<Current Collector>

For example, the size, shape, material, and structure of the current collector are not particularly limited and may be appropriately selected depending on the intended purpose.

In the conductive diamond electrode of the present disclosure, known current collector materials may be used for the current collector that is obtained by printing a paste in which the conductive diamond particles, an insulating binder, and a solvent are mixed (the paste may hereinafter be referred to as boron doped diamond (BDD) ink). The current collector may be in a form integrated with a lead.

It is possible to print the conductive diamond electrode (working electrode) of the present disclosure together with a counter electrode and a reference electrode on the same substrate to produce a detecting electrode unit, or to use the conductive diamond electrode of the present disclosure as a working electrode and form a plurality of working electrodes on the same substrate. In any case, the effect of the present disclosure can be obtained.

As the insulating binder used in the BDD ink, various polyester resins, which are condensation polymers between polyvalent carboxylic acid (dicarboxylic acid) and polyalcohol (diol), are preferable in terms of close adhesiveness with the current collector.

The insulating binder is not limited to polyester resins. Usable examples of the insulating binder include: various modified polyester resins such as urethane-modified polyester resins, epoxy-modified polyester resins, and acrylic-modified polyester; polyolefin-based resins such as polyether urethane resins, polycarbonate urethane resins, polyethylene, polypropylene, ethylene vinyl acetate polymers, and maleated polyolefin; vinyl chloride-vinyl acetate polymers, epoxy resins, phenol resins, and polyamide imide; and modified cellulose such as nitrocellulose, cellulose-acetate-butyrate (CAB), and cellulose-acetate-propionate (CAP).

The conductive diamond particles may be used without any surface treatment to the produced state of the conductive diamond particles, or may be used after some surface treatment is applied. For example, treatment by chemical modification such as hydrogen termination treatment, oxygen termination treatment, halogenation treatment, ferrocene modification treatment, sulfo-group modification treatment, quaternary ammonia group termination treatment, and carboxylic acid termination treatment (and other organic functional group modification treatment), and thermal treatment may be applied. In order to impart an electrochemical property to the conductive diamond particles, it is possible to mix (or add or bind) the conductive diamond particles with one or more kinds of oxidation-reduction catalysts or one or more kinds of mediators. Examples of the oxidation-reduction catalyst include chemical substances such as enzymes, antibodies, and metals.

It is preferable that the conductive diamond particles to be mixed in the BDD ink be added such that the volume of the conductive diamond particles is 20% or greater but 90% or less of the volume of the insulating binder.

As the solvent used in the BDD ink, a known solvent that can dissolve the insulating binder and has a low volatility can be used. That is, as the solvent, a solvent having a good compatibility with the insulating binder is used. The solvent may be formed of one kind of solvent, or may be a mixture of a plurality of kinds of solvents. Specific examples of the solvent when a polyester resin is used as the insulating binder include a solvent in which ethyl carbitol acetate (with a boiling point of 217 degrees C.) and butyl cellosolve acetate (with a boiling point of 188 degrees C.), which have a good compatibility with the polyester resin, are mixed at 75/25 (mass ratio), and a solvent in which high-boiling-point solvents having boiling points of 250 degrees C. or higher, such as methyl ether, ethyl ether, propyl ether, polypropylene glycol monomethyl ether, and tri(2-ethylhexyl) trimellitate are blended.

The method for printing the conductive diamond electrode is not particularly limited, and screen printing that allows easy control of the film thickness and patterning is preferable. However, a powder scattering coating method, a spray coating method, a spin coating method, and common printing methods such as a gravure printing method, an offset printing method, and an inkjet printing method may be used. The thickness of the film of the BDD ink formed by printing is not particularly limited.

The conductive diamond electrode of the present disclosure has a high S/B ratio and can detect a trace substance. Therefore, the conductive diamond electrode can be used as a detecting electrode of a sensor configured to detect, by an electrochemical measurement, substances such as residual chlorine, environmental hormones, arsenic, and heavy metals that hitherto have been detected by an absorptiometry method or a colorimetric method.

The S/B ratio has the same meaning as S/N ratio. A higher S/B ratio means that it has been possible to detect a trace substance at a higher accuracy.

Easy mass production of the conductive diamond electrode of the present disclosure is possible. Therefore, use of the conductive diamond electrode as a disposable electrode allows highly sensitive, quick electrochemical measurement detection of, for example, dopamine, proteins (cancer markers), oxalic acid, glucose, insulin, and histamine in blood and urine, while also allowing avoidance of risks of contamination and infection.

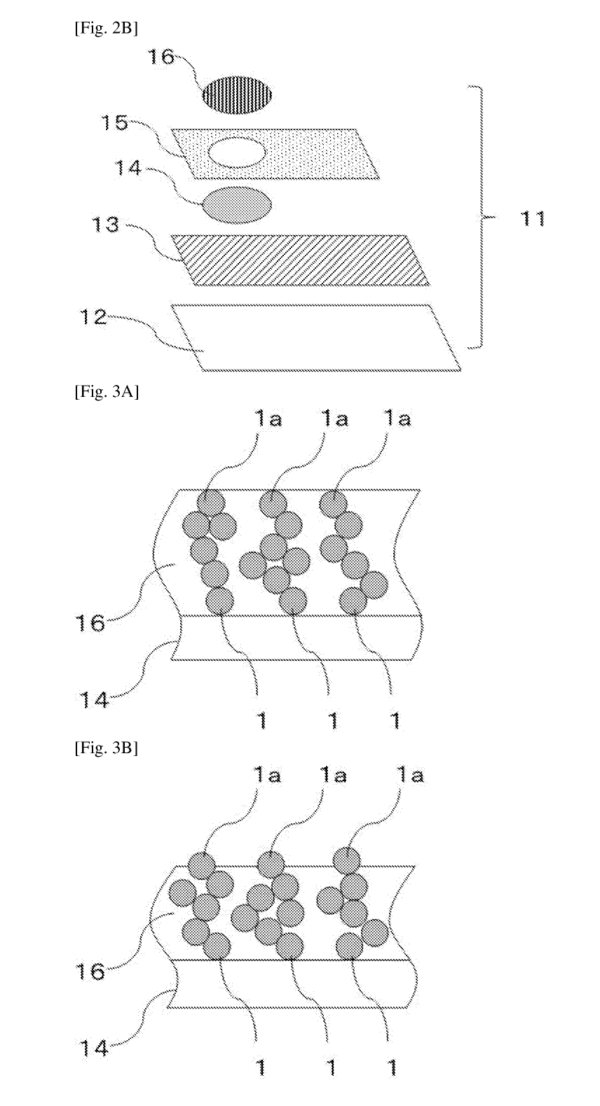

FIG. 2A is a perspective view illustrating an example of the conductive diamond electrode of the present disclosure.

As illustrated in FIG. 2A, the conductive diamond electrode 11 of the present disclosure is formed by depositing a paste, in which the conductive diamond particles 1 and the insulating binder are mixed (the paste may hereinafter be referred to as boron doped diamond (BDD) ink 16), on a current collector obtained by coating a silver paste 13 with a carbon paste 14.

FIG. 2B illustrates an exploded perspective view of the conductive diamond electrode 11.

As illustrated in FIG. 2B, in the production of the conductive diamond electrode 11, the silver paste 13 is printed on a polyimide substrate 12, and the carbon paste 14 is printed on the silver paste 13. Further, an insulating resin 15 is printed in a manner to coat the silver paste 13 on which the carbon paste 14 is printed. Here, the insulating resin 15 is printed in a manner not to coat at least part of the carbon paste 14. That is, the part of the carbon paste 14 not coated with the insulating resin 15 serves as the current collector, and this part constitutes the apparent electrode area. Furthermore, one end of the silver paste 13 is left uncoated with the insulating resin 15 to form a coupling part 13a, which serves as a coupling portion between the conductive diamond electrode 11 and a measuring instrument (detecting device) such as a potentiostat. Then, the BDD ink 16 is printed on the carbon paste 14. It is preferable to add the conductive diamond particles 1 to be mixed in the BDD ink 16 such that the volume of the conductive diamond particles is 20% or greater but 90% or less of the volume of the insulating binder.

As illustrated in FIG. 3A, when the BDD ink 16, in which the conductive diamond particles 1 are added such that the volume of the conductive diamond particles is 90% or less of the volume of the insulating binder, is printed on the carbon paste 14, the conductive diamond particles 1 agglomerate to form conductive diamond particle groups 1a. Generally, it is known that many of conductive particles such as carbon black are in the form of agglomerated masses. The conductive diamond particles 1 of the present disclosure are likewise considered to form agglomerates. When the BDD ink 16 is dried, the solvent vaporizes from the BDD ink 16 to make the film thickness of the BDD ink 16 thinner as illustrated in FIG. 3B.

As a result, it is considered that the vertical distance of the BDD ink 16 between the conductive diamond particles 1 becomes shorter and the conductive diamond particles 1 constituting the conductive diamond particle groups 1a come into close contact with each other, to form conductive diamond particle groups 1a that form electrical coupling between the conductive diamond particles 1 exposed from the surface of the BDD ink 16 and the current collector 14 through the conductive diamond particles 1. The insulating binder is present between the conductive diamond particle groups 1a in the planar direction of the BDD layer. Therefore, the surface of the electrode has a form of the conductive diamond particle groups 1a surrounded by the insulating binder being dispersed at a low density (pseudo microelectrodes).

On the other hand, the greater than 90% of the volume of the insulating binder the volume of the conductive diamond particles 1, i.e., the greater the volume ratio of the conductive diamond particles 1, the more likely the conductive diamond particle groups 1a are to electrically couple with each other in the BDD layer obtained by drying the BDD ink 16. Therefore, the diamond particle groups 1a electrically coupled with the carbon paste 14 do not become the form as pseudo microelectrodes present at a low density in the surface of the conductive diamond electrode 11. Further, when the volume of the conductive diamond particles 1 is less than 20% of the volume of the insulating binder, the ratio of conductive diamond particles 1 that cannot be electrically coupled with the carbon paste 14 as being surrounded by the insulating binder increases in the BDD layer, to decrease a faradaic current that is to flow in the conductive diamond electrode 11.

The conductive diamond electrode of the present disclosure has a high chemical stability and a high detection sensitivity. Therefore, the conductive diamond electrode can be used as a detecting electrode of various sensors, and a testing device using the detecting electrode can be built up.

Easy mass production of the conductive diamond electrode of the present disclosure is possible. Therefore, the conductive diamond electrode can be used as a disposable electrode. This makes it possible to avoid risks of contamination and infection in bio sensing.

(Testing Device)

A testing device of the present disclosure includes the conductive diamond electrode of the present disclosure and further includes other members as needed.

For example, by a glucose oxidoreductase being placed on the conductive diamond particles, the testing device can be used as a detecting electrode of a blood glucose monitoring device.

Furthermore, diamond has an inactive surface, and hence is less likely to adsorb proteins. Therefore, the conductive diamond electrode of the present disclosure can directly electrochemically oxidize amino acid residues in a protein, and can detect a protein present in a solution with a high sensitivity. Accordingly, the testing device of the present disclosure can be used for simple, low-cost tests that do not involve expensive reagents and complicated steps in, for example, various pathological diagnoses and infectious disease tests.

### EXAMPLES

The present disclosure will be described by way of Examples. However, the present disclosure should not be construed as being limited to the Examples.

### Example 1

<Method for Producing Conductive Diamond Particles (BDDP)>

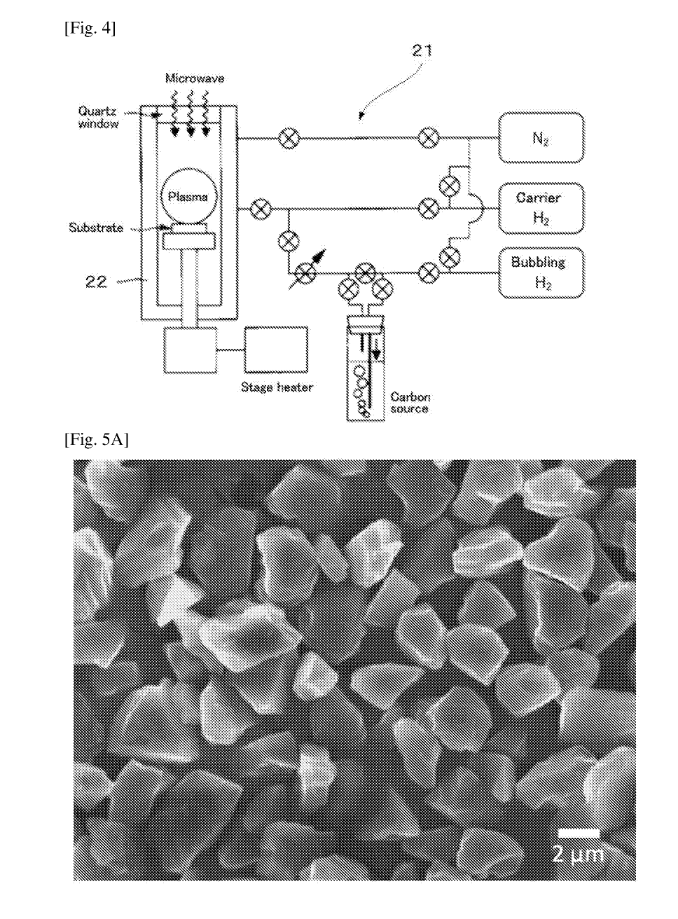

In Examples described below, a microwave plasma CVD apparatus 21 (MPCVD equipment, available from ASTex Microwave Systems) was used as a unit configured to form boron-doped diamond films (BDD films) on the particulate bases. FIG. 4 schematically illustrates the MPCVD apparatus 21.

As the particulate bases 2, a pulverized artificial diamond powder (DP, available from Element Six, Micron+MDA, with a manufacturer's nominal particle diameter of from 3 micrometers through 6 micrometers) was used.

The diamond powder contained metal components and various sp² carbons as impurities. These impurities would adversely affect the final product. Hence, in order to remove these impurities, the diamond powder was treated for 30 minutes with aqua regia heated to 60 degrees C., and for 30 minutes with 30% hydrogen peroxide water likewise heated to 60 degrees C., to remove impurities contained in the diamond powder. The washed diamond powder was ultrasonically washed in ultrapure water/2-propanol/acetone, and dried.

The diamond powder, of which surface was washed, was stored in an amount of 1.0 g in a storing container 22 in the MPCVD apparatus 21 to serve as bases, and boron-doped diamond films were grown on the surface layers of the diamond powder.

As a carbon source, an acetone/methanol mixture solution in which trimethoxyborane (B(OCH₃)₃) was dissolved such that the boron concentration ratio (B/C) would be 20,000 ppm was used. With the diamond powder, which was stored in the storing container 22, irradiated with a microwave through a quartz window, trimethoxyborane and hydrogen were supplied into the storing container 22 to grow boron-doped diamond films on the surface of the diamond powder, to obtain conductive diamond particles. The microwave output was fixed at 1,300 W, and the growing time was 8 hours. The detailed reaction conditions are presented in Table 1.

TABLE 1

| Parameter | Value | |
|---|---|---|
| Microwave output | 1,300 | W |
| Carrier gas flow rate | 400 | sccm |
| Bubbling gas flow rate | 0.5 | sccm |
| Chamber internal pressure | 50 | Torr |
| Stage temperature | 800 | degrees C. |
| Growing time | 8 | h |

After BDD layers were grown, the resultant was heated by a muffle furnace in the air at 425 degrees C. for 5 hours, to remove graphite impurities produced during growth of the BDD layers. Subsequently, hydrogen termination treatment was applied to the surface oxidized by the thermal treatment. The treatment conditions of the hydrogen termination treatment were a hydrogen flow rate of 100 sccm, a pressure of 20 Torr, a microwave output of 500 W, a stage temperature of 800 degrees C., and 1 hour of hydrogen plasma treatment.

<Measurement of Particle Size Distribution>

The particle size distributions of the DP used as the bases and BDDP, which was the DP after BDD layers were formed, were measured with a dynamic light scattering measuring instrument (DLS measurement, NICOMP 380 available from Particle Sizing Systems, LLC), to calculate average particle diameters. As a result, the average particle diameter of the DP was 2,649 nm, and the average particle diameter of the BDDP was 3,558 nm.

Based on the results, the average thickness of the BDD layers formed on the bases was calculated as 455 nm. Here, the average thickness of the BDD layers was obtained according to (average particle diameter of BDDP−average particle diameter of DP)/2. Further, the average volume ratio of the BDD layers in the BDDP calculated based on this result was 58.7%. Here, the average volume ratio of the BDD layers in the BDDP represents the volume of the BDD layer in the volume of the BDDP when the particle diameters before and after the BDD layers were formed were assumed to be the same as the average particle diameter of the DP and the average particle diameter of the BDDP, respectively.

<Measurement of Powder Conductivity>

A system was formed by filling a glass capillary having an internal diameter of 1.0 mm with the BDDP, and then inserting 0.8 mm copper wires from both ends of the glass capillary. The copper wires were coupled with a potentiostat (HZ-5000, available from Hokuto Denko Corp.), to perform current-voltage measurement of the BDDP filled layer. The measurement was performed at an applied voltage of from −0.5 V through 0.5 V and at a sweeping rate of 100 mV/s, to obtain a current-voltage curve. Using the slope of the obtained straight line, the horizontal length of the BDDP in the glass capillary, and the internal diameter of the glass capillary, the powder conductivity σ of the BDDP was calculated according to a mathematical formula 1 below. As a result, the powder conductivity σ was 0.62 S/cm.

σ=L/(RA) Mathematical formula 1

In mathematical formula 1, R represents a resistance (the slope of the straight line), A represents a cross-sectional area of the capillary, and L represents the length of the BDDP layer.

<Electron Microscopic Observation>

The particle surfaces of the DP used as the bases and the BDDP after the BDD layers were formed were observed with a scanning electron microscope (JSM-7600F, available from JASCO Corporation, at a magnification of ×4,500). The results are illustrated in FIG. 5A and FIG. 5B.

FIG. 5A illustrates the surface of the DP used as the bases, and FIG. 5B illustrates the surface image of the BDDP. Because the DP was an insulator, the DP underwent a charging phenomenon called “charge up” during the SEM observation, to appear white in part of the image. In FIG. 5A, edges of the particles were observed as white streaks due to the charge up. On the other hand, in FIG. 5B, no such white streaks were observed because the DP had been coated with the conductive boron-doped diamond films. That is, it was possible to confirm that the BDDP had been formed. Further, the edge profiles of the particles were rounder in FIG. 5B than in FIG. 5A. Also from this fact, it was possible to confirm that the BDDP had been formed.

<Raman Measurement>

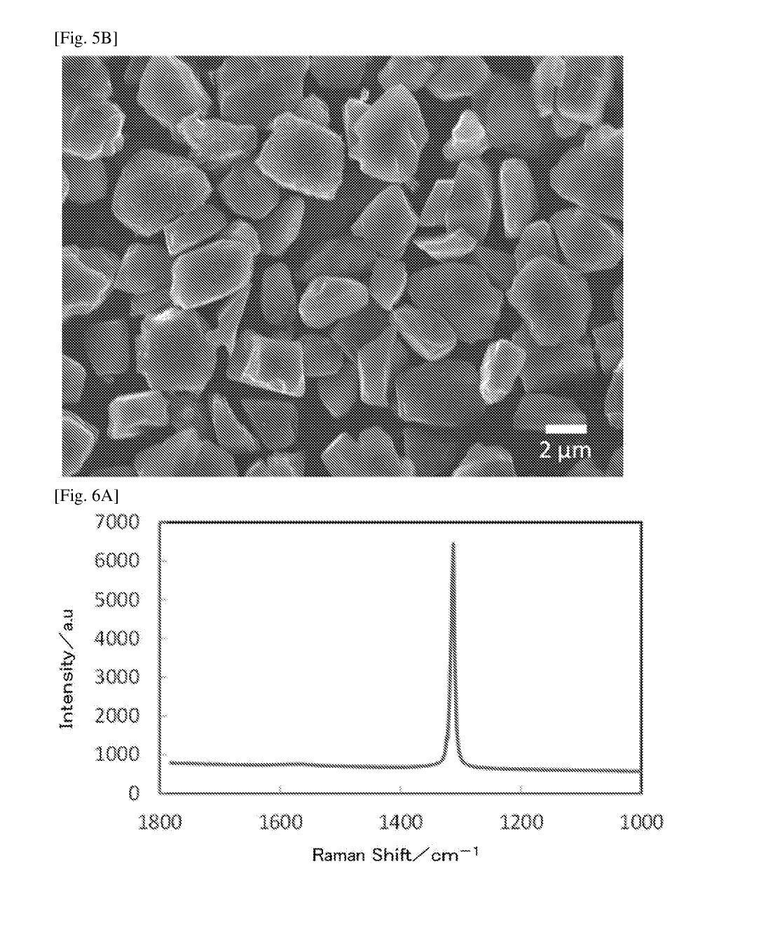

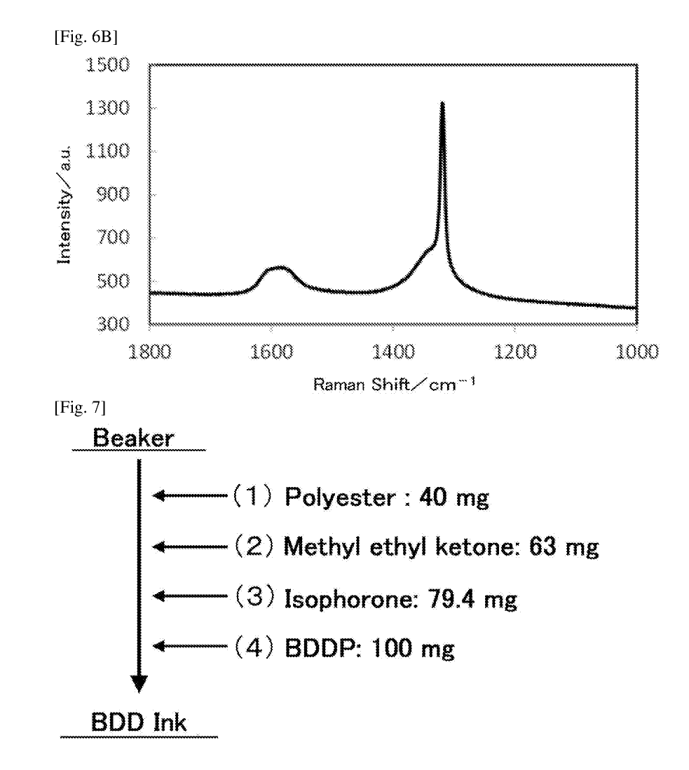

Raman measurement of the obtained conductive diamond particles was performed with a Raman spectrometer (NSR-5100, available from JASCO Corporation). The measurement result of Example 1 is illustrated in FIG. 6A.

In the Raman measurement, the measurement conditions were a measurement range of from 1,000 cm⁻¹ through 1,800 cm⁻¹, a laser wavelength of 532 nm, and a cumulative number of times of 5 times.

### Example 2

Conductive diamond particles were produced in the same manner as in Example 1 except that unlike in the production of the conductive diamond particles in Example 1, the growing time of the boron-doped diamond films by the MPCVD apparatus was 4 hours, and were evaluated in the same manners as in Example 1.

### Example 3

Conductive diamond particles were produced in the same manner as in Example 1 except that unlike in the production of the conductive diamond particles in Example 1, the growing time of the boron-doped diamond films by the MPCVD apparatus was 12 hours, and were evaluated in the same manners as in Example 1.

### Example 4

Conductive diamond particles were produced in the same manner as in Example 1 except that unlike in the production of the conductive diamond particles in Example 1, a pulverized artificial diamond powder (available from Element Six, Micron+MDA, with a manufacturer's nominal particle diameter of from 0.5 micrometers through 1 micrometer) was used as the particulate bases, and were evaluated in the same manners as in Example 1.

### Example 5

Conductive diamond particles were produced in the same manner as in Example 1 except that unlike in the production of the conductive diamond particles in Example 1, a pulverized artificial diamond powder (available from Element Six, Micron+MDA, with a manufacturer's nominal particle diameter of from 1 micrometer through 3 micrometers) was used as the particulate bases, and were evaluated in the same manners as in Example 1.

### Comparative Example 1

Conductive diamond particles were produced in the same manner as in Example 1 except that unlike in the production of the conductive diamond particles in Example 1, a pulverized artificial diamond powder (available from Element Six, Micron+MDA, with a manufacturer's nominal particle diameter of from 0 micrometers through 0.5 micrometers) was used as the particulate bases, and were evaluated in the same manners as in Example 1. Raman measurement of the obtained conductive diamond particles was performed in the same manner as in Example 1. The measurement result of Comparative Example 1 is illustrated in FIG. 6B.

The average particle diameters, the powder conductivity, and the Raman spectrum measurement result of each of Examples 1 to 5 and Comparative Example 1 are presented in Table 2-1 and Table 2-2.

TABLE 2-1

| | | Average particle diameters of | | Average | Average | |
|---|---|---|---|---|---|---|
| | | particulate bases | | thickness | volume | Powder |
| | CVD time | Before BDD | After BDD | (nm) of | ratio (%) of | conductivity |
| | (hour) | coating (nm) | coating (nm) | BDD layers | BDD layers | (S/cm) |
| Ex. 1 | 8 | 2,649 | 3,558 | 454.5 | 58.7 | 0.62 |
| Ex. 2 | 4 | 2,649 | 3,043 | 197.0 | 34.0 | 0.42 |
| Ex. 3 | 12 | 2,649 | 3,946 | 648.5 | 69.7 | 1.7 |
| Ex. 4 | 8 | 436 | 647 | 105.5 | 69.4 | 0.35 |
| Ex. 5 | 8 | 1,647 | 1,974 | 163.5 | 41.9 | 0.83 |
| Comp. Ex. 1 | 8 | 301 | 366 | 32.5 | 44.4 | 0.34 |

TABLE 2-2

| | Raman spectrum | | |
|---|---|---|---|
| | Peak intensity | Peak intensity | Intensity ratio |
| | (a.u.) at | (a.u.) at | (1,580 cm⁻¹/ |
| | 1,580 cm⁻¹ | 1,332 cm⁻¹ | 1,332 cm⁻¹) |
| Ex. 1 | 30 | 5,720 | 0.0052 |
| Ex. 2 | 38 | 8,872 | 0.0043 |
| Ex. 3 | 27 | 1,300 | 0.021 |
| Ex. 4 | 8 | 96 | 0.083 |
| Ex. 5 | 4 | 116 | 0.034 |
| Comp. | 102 | 1,112 | 0.092 |
| Ex. 1 | | | |

From the results of Table 2-1 and Table 2-2, in Comparative Example 1, because the average particle diameter of the conductive diamond after BDD coating was 0.5 micrometers or less, the ratio of the intensity at 1,580 cm⁻¹ to the intensity at 1,332 cm⁻¹ was greater than 0.090 in the Raman spectrum. This indicates that the amount of sp² carbon mixed into the boron-doped diamond films was relatively high, to make the crystal quality of the boron-doped diamond films low. Due to this factor, the powder conductivity was only 0.34 S/cm.

On the other hand, in Examples 1 to 5, because the average particle diameter of the conductive diamond was greater than 0.5 micrometers, the film formation speed of the boron-doped diamond films was sufficiently high. Along with this factor, the ratio of the intensity at 1,580 cm⁻¹ to the intensity at 1,332 cm⁻¹ in the Raman spectrum was less than 0.090 in all of these Examples. Such a high crystal quality was reflected in the powder conductivity, which was greater than 0.34 S/cm in all of Examples 1 to 5.

### Example 6

<Method for Producing Screen-Printed Electrode>

1. Preparation of Boron-Doped Diamond (BDD) Ink

FIG. 7 illustrates a flow diagram of a method for preparing a BDD ink 6. The method for preparing a BDD ink 6 will be described with reference to FIG. 7.

First, as an insulating binder, a polyester resin (product name: VYLON GK-140, available from Toyobo Co., Ltd.) was weighed out in an amount of 40 mg in a beaker. Next, with a Pasteur pipette, 5 droplets (63.0 mg) of methyl ethyl ketone and 5 droplets (79.4 mg) of isophorone were added to the polyester resin (40 mg), to dissolve the polyester resin. Here, methyl ethyl ketone was additionally added appropriately, because methyl ethyl ketone would easily volatilize. After the polyester resin was dissolved, the BDDP produced in Example 1 was added in an amount of 100 mg and sufficiently dispersed, to prepare a BDD ink 6.

2. Screen Printing

A conductive diamond electrode 11 was produced using a screen printer (available from New Long, LS-150TV). Screen printing is one of stencil printing methods, and is a printing method of rubbing an ink on a target from holes opened in a printing plate.

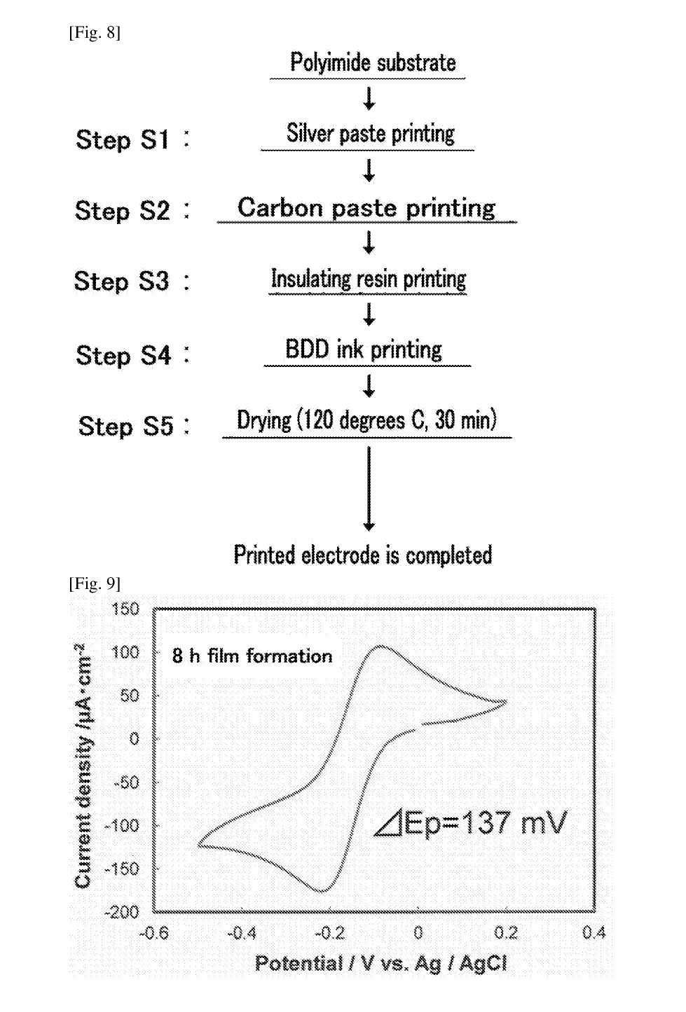

A method for producing a conductive diamond electrode using a screen printer will be described with reference to the perspective view of the appearance of a conductive diamond electrode 11 illustrated in FIG. 2A (and the exploded perspective view illustrated in FIG. 2B) and the flow diagram for production of the conductive diamond electrode 11 illustrated in FIG. 8.

First, a silver paste 13 (ECM-100 AF5000, available from Taiyo Ink Mfg. Co., Ltd.) was printed on a polyimide substrate 12 (product name: KAPTON FILM, available from Du Pont-Toray Co., Ltd.) (step S1).

Next, a carbon paste 14 (JELCON CH-10, available from Jujo Chemical Co., Ltd.) was printed on the printed silver paste 13 (step S2).

Further, an insulating resin 15 (TF-200FR1, available from Taiyo Ink Mfg. Co., Ltd.), which was a kind of a resist ink, was printed in a manner to coat the silver paste 13 (step S3).

Here, the insulating resin 15 was printed in a manner not to coat at least part of the carbon paste 14 formed in the step S2. The carbon paste 14 on which the insulating resin 15 was not printed would serve as the current collector of the conductive diamond electrode 11.

Then, the BDD ink 6 was printed on the carbon paste 14 (step S4).

After the BDD ink 6 was printed, the resultant was heated at 120 degrees C. for 30 minutes, to produce the conductive diamond electrode 11 (step S5).

<Evaluation of Screen-Printed Electrode>

—Electrochemical Property in Hexaammineruthenium (III) Chloride ([Ru(NH₃)₆]C₁₃) Aqueous Solution—

Using the screen-printed electrode, a cyclic voltammetry (CV) measurement was performed in a sodium sulfate aqueous solution containing hexaammineruthenium (III) chloride, which was a redox species used for evaluation of typical electrochemical properties.

The CV measurement was performed using a potentiostat (HZ-5000, available from Hokuto Denko Corp.) based on a three-electrode system. The configuration of the measuring instrument and the measurement conditions are described below.
Working electrode: screen-printed electrode
Counter electrode: platinum wire
Measurement solution: hexaammineruthenium (III) chloride (1.0 mmol/L)-perchloric acid aqueous solution (0.1 mol/L)
Reference electrode: silver/silver chloride (Ag/AgCl)/saturated potassium chloride electrode
Sweeping rate: 50 mV/s

FIG. 9 illustrates the CV measurement result. Here, ΔEp, which was defined as the difference between a potential at which an oxidation current reached a peak and a potential at which a reduction current reached a peak, was calculated, and as a result, was 137 mV.

3. Detection of Bovine Serum Albumin

In order to evaluate whether the screen-printed electrode was capable of detecting a protein present in an aqueous solution with a high sensitivity, CV measurement was performed in a phosphate buffered saline (PBS) containing a bovine serum albumin (BSA). The configuration of the measuring instrument and the measurement conditions are described below.
Working electrode: screen-printed electrode
Counter electrode: platinum wire
Measurement solution: PBS (0.1 mol/L, pH=7.0) containing BSA (1,000 mg/L), or PBS only
Reference electrode: silver/silver chloride (Ag/AgCl)/saturated potassium chloride electrode
Sweeping rate: 50 mV/s

A CV curve measured with the PBS only was a base line, and a CV curve measured with the PBS containing the BSA was a signal line. Based on these curves, the values on the base line (B) and signal line (S) at +0.70 V with respect to the reference electrode were obtained, and the ratio between the values was calculated as a S/B ratio.

### Example 7

An electrode was produced in the same manner as in Example 6 except that unlike in the production of the screen-printed electrode in Example 6, the BDDP produced in Example 2 was used, and electrochemical evaluation of the electrode was performed.

### Example 8

An electrode was produced in the same manner as in Example 6 except that unlike in the production of the screen-printed electrode in Example 6, the BDDP produced in Example 3 was used, and electrochemical evaluation of the electrode was performed.

### Example 9

An electrode was produced in the same manner as in Example 6 except that unlike in the production of the screen-printed electrode in Example 6, the BDDP produced in Example 4 was used, and electrochemical evaluation of the electrode was performed.

### Example 10

An electrode was produced in the same manner as in Example 6 except that unlike in the production of the screen-printed electrode in Example 6, the BDDP produced in Example 5 was used, and electrochemical evaluation of the electrode was performed.

### Comparative Example 2

An electrode was produced in the same manner as in Example 6 except that unlike in the production of the screen-printed electrode in Example 6, the BDDP produced in Comparative Example 1 was used, and electrochemical evaluation of the electrode was performed.

ΔEp obtained by electrochemical measurement of each electrode is presented in Table 3. A S/B ratio obtained by electrochemical measurement of each electrode is also presented in Table 3. The S/B ratio has the same meaning as S/N ratio. A higher S/B ratio means that it was possible to detect a protein at a higher accuracy.

TABLE 3

| | | Evaluation of screen-printed electrode | | | |
|---|---|---|---|---|---|
| | | | Bovine serum albumin | | |
| | | | S (+0.70 V) | B (+0.70 V) | |
| | | | (micro- | (micro- | |
| | | [Ru(NH₃)₆]C₁₈ | ampere/ | ampere/ | S/B |
| | BDDP | ΔEp (mV) | cm²) | cm²) | ratio |
| Ex. 6 | Ex. 1 | 137 | 1.11 | 1.05 | 1.06 |
| Ex. 7 | Ex. 2 | 127 | 1.88 | 1.59 | 1.18 |
| Ex. 8 | Ex. 3 | 118 | 0.71 | 0.98 | 0.72 |
| Ex. 9 | Ex. 4 | 148 | 1.93 | 3.77 | 0.51 |
| Ex. 10 | Ex. 5 | 97 | 3.04 | 1.94 | 1.57 |
| Comp. | Comp. | 168 | 0.031 | 0.085 | 0.36 |
| Ex. 2 | Ex. 1 | | | | |

From the results of Table 2-1 and Table 2-2, the BDDPs used in the conductive diamond electrodes of Examples 6 to 10 were higher in crystal quality and powder conductivity than the BDDP used in the conductive diamond electrode of Comparative Example 2.

Meanwhile, it is known that ΔEp has an inclination of being high when an electrode has an insufficient conductivity. In this case, the lower the ΔEp, the higher the conductivity in the vertical direction (a direction from the surface of the electrode toward the carbon paste collector electrode) of the electrode.

As a result of this evaluation, all of Examples 6 to 10 were lower in ΔEp than Comparative Example 2. That is, use of the BDDPs having a high powder conductivity succeeded in producing conductive diamond electrodes having a high conductivity. Furthermore, all of Examples 6 to 10 were higher in S/B ratio than Comparative Example 2. That is, testing devices using the conductive diamond electrodes of the present disclosure were capable of detecting a trace protein in an aqueous solution at a high accuracy.

The foregoing proves that the present disclosure was able to obtain conductive diamond particles having a high crystal quality easily. Furthermore, a conductive diamond electrode produced by producing a BDD ink formed of the conductive diamond particles and an insulating binder and depositing the BDD ink on a current collector was able to build a testing device having a high accuracy.

Aspects of the present disclosure are as follows, for example

<1> Conductive diamond particles including:

particulate bases; and

boron-doped diamond films coated on at least part of surfaces of the particulate bases,

wherein an average particle diameter of the conductive diamond particles is greater than 0.5 micrometers, and

wherein in Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090.

<2> The conductive diamond particles according to <1>,

wherein an average particle diameter of the conductive diamond particles is 0.6 micrometers or greater but less than 8.0 micrometers.

<3> The conductive diamond particles according to <1> or <2>,

wherein the particulate bases contain at least any one selected from the group consisting of natural diamond particles and synthetic diamond particles.

<4> The conductive diamond particles according to any one of <1> to <3>,

wherein an average particle diameter of the particulate bases is greater than 0.4 micrometers.

<5> The conductive diamond particles according to any one of <1> to <4>,

wherein an average particle diameter of the particulate bases is 1 micrometer or greater.

<6> The conductive diamond particles according to any one of <1> to <5>,

wherein the boron-doped diamond films are formed by a chemical vapor deposition method.

<7> The conductive diamond particles according to any one of <1> to <6>,

wherein the boron-doped diamond films are formed by a plasma CVD method.

<8> The conductive diamond particles according to any one of <1> to <7>,

wherein an amount of boron doped in diamond in the boron-doped diamond films is 10 ppm or greater of carbon constituting the diamond.

<9> A conductive diamond electrode including:

a current collector; and

conductive diamond particles provided on the current collector and electrically coupled to the current collector,

wherein the conductive diamond particles are the conductive diamond particles according to any one of <1> to <8>.

<10> A testing device including

the conductive diamond electrode according to <9>.

The conductive diamond particles according to any one of <1> to <8>, the conductive diamond electrode according to <9>, and the testing device according to <10> can solve the various problems in the related art and can achieve the object of the present disclosure.

### REFERENCE SIGNS LIST

1: conductive diamond particle
1a: conductive diamond particle groups
2: particulate base
3: boron-doped diamond film
11: conductive diamond electrode
12: polyimide substrate
13: silver paste
13a: coupling part
14: carbon paste (current collector)
15: insulating resin
16: BDD ink
21: MPCVD apparatus
22: storing container

1-6. (canceled)

7. Conductive diamond particles, comprising:
particulate bases; and
boron-doped diamond films on at least part of surfaces of the particulate bases,
wherein an average particle diameter of the conductive diamond particles is greater than 0.5 micrometers,
wherein in Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090, and
wherein an average particle diameter of the particulate bases is greater than 0.4 micrometers but smaller than 8.0 micrometers.

8. The conductive diamond particles according to claim 7,
wherein the particulate bases comprise at least any one selected from the group consisting of natural diamond particles and synthetic diamond particles.

9. The conductive diamond particles according to claim 7,
wherein the boron-doped diamond films are formed by a chemical vapor deposition method.

10. A conductive diamond electrode, comprising:
a current collector; and
conductive diamond particles provided on the current collector and electrically coupled to the current collector,
wherein the conductive diamond particles comprise conductive diamond particles including:
particulate bases; and
boron-doped diamond films on at least part of surfaces of the particulate bases,
wherein an average particle diameter of the conductive diamond particles is greater than 0.5 micrometers,
wherein in Raman spectrum measurement of the conductive diamond particles at an excitation wavelength of 532 micrometers, a ratio of an intensity of the conductive diamond particles at 1,580 cm⁻¹ to an intensity of the conductive diamond particles at 1,332 cm⁻¹ is less than 0.090, and
wherein an average particle diameter of the particulate bases is greater than 0.4 micrometers but smaller than 8.0 micrometers.

11. A testing device, comprising:
the conductive diamond electrode according to claim 9.
